(19) United States
(12) Patent Application Publication
(10) Pub. No.: US 2019/0115522 A1
(43) Pub. Date: Apr. 18, 2019

(54) PIEZOELECTRIC TACTILE SENSOR AND KEYBOARD DEVICE

(71) Applicant: TOSHIBA TEC KABUSHIKI KAISHA, Tokyo (JP)

(72) Inventors: MengFei WONG, Mishima Shizuoka (JP); Atsushi KUBOTA, Sunto Shizuoka (JP); Takashi KADO, Mishima Shizuoka (JP)

(21) Appl. No.: 16/057,543

(22) Filed: Aug. 7, 2018

(30) Foreign Application Priority Data
Oct. 18, 2017 (JP) 2017-201876

(51) Int. Cl. H01L 41/113; H01L 41/047; H01L 41/08; H01L 41/053; H03K 17/96

(52) U.S. Cl. CPC H01L 41/1132; H01L 41/047; H03K 17/9643; H01L 41/053; H01L 41/0805

(57) ABSTRACT

A piezoelectric tactile sensor includes a support body having one or more openings, a diaphragm formed on a surface of the support body, one or more piezoelectric films respectively formed above the openings and on a surface of the diaphragm, and two electrodes that sandwich each of the piezoelectric films. Each of the piezoelectric films has a diameter smaller than a diameter of a corresponding one of the openings and outputs a voltage to the two electrodes in response to a deflection of the diaphragm.

### CROSS-REFERENCE TO RELATED APPLICATION

This application is based upon and claims the benefit of priority from Japanese Patent Application No. 2017-201876, filed Oct. 18, 2017, the entire contents of which are incorporated herein by reference.

### FIELD

Embodiments described herein relate generally to a piezoelectric tactile sensor and a keyboard device.

### BACKGROUND

A piezoelectric material is known to have a direct piezoelectric effect in which a charge (voltage) is generated in proportion to applied mechanical stress, and also have an inverse piezoelectric effect in which the body is deformed when an electric field is applied in contrast.

In the related art, the direct piezoelectric effect is applied to a piezoelectric ultrasonic sensor element to detect vibration using a diaphragm. Such a sensor element includes a substrate having openings and the diaphragm mounted on this substrate such that the openings are covered. In the manufacturing process, the piezoelectric is formed between two electrodes (upper electrode and lower electrode) on one surface side of the diaphragm so as to form a vibration detector. In the operating condition, in response to an ultrasonic wave propagating through a medium such as air, the diaphragm is deflected in the openings, which causes the piezoelectric body to expand and contract in a plane direction of the substrate. As a result, the piezoelectric generates a voltage due to the direct piezoelectric effect and outputs the voltage through the two electrodes.

In general, the ultrasonic sensor element is applicable to a pressure sensor or a tactile sensor. For example, if a pressure is applied to the diaphragm in a downward direction perpendicular to the plane direction, the diaphragm is also deflected toward the downward direction and the piezoelectric body outputs a voltage through the two electrodes, thereby enabling the sensor to detect slight change in pressure.

According to the piezoelectric ultrasonic sensor element using the diaphragm in the related art, in order to draw the upper electrode and the lower electrode outward of the diaphragm, the piezoelectric body located between the upper electrode and the lower electrode extends outward of the opening of the substrate. Accordingly, the piezoelectric body has a cantilevered structure in an extension portion extending outward of the opening portion. Therefore, in response to the deflection, stress is caused by a bending moment in the extension portion of the piezoelectric body. Since the stress affects the deformation of the diaphragm, an output voltage of the ultrasonic sensor element may vary over time.

### DESCRIPTION OF THE DRAWINGS

FIG. 1 is a plan view illustrating a configuration of a piezoelectric tactile sensor according to a first embodiment.

FIG. 2 is a sectional view taken along line II-II in FIG. 1.

FIG. 3 is a sectional view taken along line III-III in FIG. 1.

FIG. 4 is a plan view illustrating a configuration of a piezoelectric tactile sensor according to a second embodiment.

FIG. 5 is a plan view illustrating a configuration of a piezoelectric tactile sensor according to a third embodiment.

FIG. 6 is a sectional view taken along line VI-VI in FIG. 5.

FIG. 7 is an exploded perspective view illustrating a configuration example of a keyboard device in an application example of the piezoelectric tactile sensor according to the first embodiment.

FIG. 8 is a characteristic diagram illustrating an example of a generated voltage in the application example in FIG. 7.

### DETAILED DESCRIPTION

Embodiments described herein aim to provide a piezoelectric tactile sensor capable of suppressing variations in an output voltage so as to improve long-term reliability, and a keyboard device using this piezoelectric tactile sensor.

A piezoelectric tactile sensor according to an embodiment includes a support body having one or more openings, a diaphragm formed on a surface of the support body, one or more piezoelectric films respectively formed above the openings and on a surface of the diaphragm, and two electrodes that sandwich each of the piezoelectric film. Each of the piezoelectric films has a diameter smaller than a diameter of a corresponding one of the openings and outputs a voltage to the two electrodes in response to a deflection of the diaphragm.

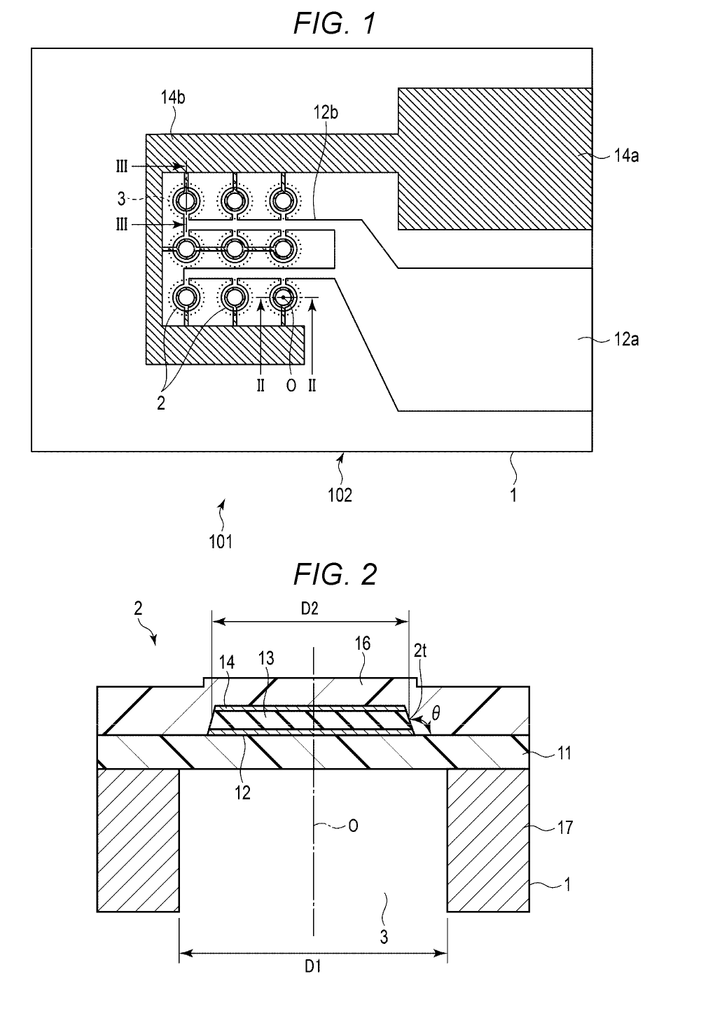

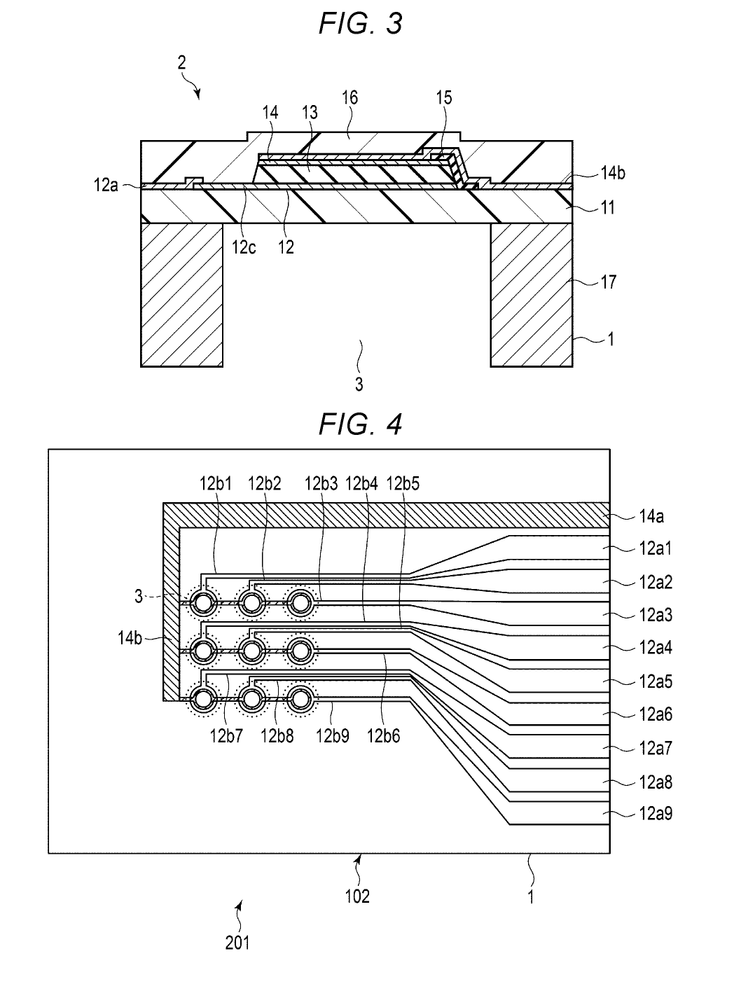

Hereinafter, a configuration of a piezoelectric tactile sensor according to a first embodiment will be described with reference to FIGS. 1 to 3. FIG. 1 is a plan view illustrating a configuration of the piezoelectric tactile sensor according to the first embodiment. FIG. 2 is a sectional view taken along line II-II in FIG. 1, and FIG. 3 is a sectional view taken along line III-III in FIG. 1.

As illustrated in FIG. 1, a piezoelectric tactile sensor 101 according to the first embodiment has a sensor element array 102. In the sensor element array 102, a plurality of sensor elements 2, for example, nine circular sensor elements 2 are arranged in a 3×3 matrix on a substrate 1 serving as a support body.

As an example, the substrate 1 is formed of a single crystal silicon wafer having a thickness of 500 μm, for example. An opening portion 3 is formed inside the substrate 1 having a circular hole for detecting pressure. In an embodiment, the opening portions 3 are respectively formed at nine positions as many as the number of the sensor elements 2. As illustrated in FIG. 2, a diameter D1 of the opening portion 3 is 200 μm as an example. The opening portion 3 is formed by drilling a hole from a lower surface of the substrate 1 through dry etching. A center-to-center distance of the adjacent opening portions 3 of the substrate 1 is 250 μm, for example.

FIGS. 2 and 3 illustrate a sectional structure of one sensor element 2. FIG. 2 is a sectional view taken along line II-II in FIG. 1, and FIG. 3 is a sectional view taken along line in FIG. 1. The sensor element 2 includes a diaphragm 11, a first electrode 12 (also referred to as a lower electrode), a piezoelectric film 13, a second electrode 14 (also referred to as an upper electrode), an insulating layer 15, and a protective layer 16.

The diaphragm 11 is integrally formed with the substrate 1 so as to cover an upper surface of the opening portion 3. The diaphragm 11 is formed by heating the substrate 1 at high temperature before the opening portion 3. In this manner, the diaphragm 11 is formed of silicon dioxide formed on a surface of the silicon wafer of the substrate 1. It is preferable that a thickness of the diaphragm 11 falls within a range of 1 to 50 μm. As an example, the thickness is set to 4 μm.

In the description, embodiments are described assuming that a direction where the opening portion 3 is formed in the substrate 1 is referred to a downward direction (see FIG. 2).

The first electrode 12, the piezoelectric film 13, and the second electrode 14 are stacked on an upper surface of the diaphragm 11. As an example, in the first electrode 12, the piezoelectric film 13, and the second electrode 14, platinum, PZT lead zirconate titanate (PZT), and platinum are respectively deposited using a sputtering method. As an example, the thickness of the first electrode 12 and the second electrode 14 is 0.1 to 0.2 μm. As an example, the thickness of the piezoelectric film 13 is 2 μm. The PZT of the piezoelectric film 13 may also be deposited using a spin coating method.

In order to obtain the piezoelectric film 13 having a high crystal orientation, the piezoelectric film 13 is formed on the polycrystalline first electrode 12 having a strong orientation. The piezoelectric film 13 has an orientation direction (polarization direction) determined when the film is deposited. Polarization is generated in the thickness direction. The piezoelectric film 13 is deposited on the first electrode 12 by using the sputtering method. Accordingly, the polarization direction of the piezoelectric film 13 is aligned with a direction from the first electrode 12 toward the second electrode 14.

The diaphragm 11 is deflected in the downward direction in FIG. 2 in response to applied pressure in a direction opposite to the polarization direction. The piezoelectric film 13 expands in a direction orthogonal to the film thickness (the plane direction). Here, the substrate 1 has a frame portion 17 which supports the diaphragm 11 by using a wall portion around the opening portion 3. If the piezoelectric film 13 extends to a portion of the frame portion 17, due to a circumferential fixed end support structure of an extension portion of the piezoelectric film 13, the diaphragm 11 is deflected less.

In this embodiment, the first electrode 12, the piezoelectric film 13, and the second electrode 14 are formed in a circular shape concentric with the center O of the opening portion 3 having the circular hole. An outer diameter of the circular shape of the first electrode 12, the piezoelectric film 13, and the second electrode 14 is smaller than a diameter D1 of the opening portion 3, e.g., 200 μm. Here, as an example, an outer diameter D2 of the piezoelectric film 13 is set to 140 μm.

As illustrated in FIG. 1, the sensor element array 102 has a first electrode terminal portion 12a, a first electrode lead wiring portion 12b, a second electrode terminal portion 14a, and a second electrode lead wiring portion 14b on an upper surface of the diaphragm 11. The first electrode terminal portion 12a and the second electrode terminal portion 14a are arranged in an end portion of the substrate 1. One end of the first electrode lead wiring portion 12b is connected to the first electrode terminal portion 12a. The other end of the first electrode lead wiring portion 12b is connected to the first electrode 12 of each of the nine sensor elements 2. Similarly, one end of the second electrode lead wiring portion 14b is connected to the second electrode terminal portion 14a. The other end of the second electrode lead wiring portion 14b is connected to the second electrode 14 of each of the nine sensor elements 2.

As illustrated in FIG. 3, a first electrode extension portion 12c extending radially outward (leftward in FIG. 3) is formed in a portion of an outer peripheral portion of the first electrode 12. The first electrode extension portion 12c extends outward from a position corresponding to the outer peripheral surface of the opening portion 3. The other end of the first electrode lead wiring portion 12b is connected to a tip end of the first electrode extension portion 12c.

In a portion of the outer peripheral portion of the piezoelectric film 13, the insulating layer 15 is formed at a position corresponding to the second electrode lead wiring portion 14b. The insulating layer 15 prevents the second electrode lead wiring portion 14b and the first electrode 12 from electrically contacting with each other at the outer peripheral portion of the piezoelectric film 13. As an example, the insulating layer 15 is formed by depositing silicon dioxide through a tetraethoxysilane-chemical vapor deposition (TEOS-CVD) method. As an example, the thickness of the insulating layer 15 is set to 0.5 μm.

The first electrode lead wiring portion 12b and the second electrode lead wiring portion 14b are formed on the insulating layer 15. The first electrode lead wiring portion 12b is connected to the first electrode extension portion 12c of the first electrode 12. The second electrode lead wiring portion 14b is connected to the second electrode 14. As an example, the first electrode lead wiring portion 12b and the second electrode lead wiring portion 14b are formed by depositing gold through a sputtering method. As an example, the thickness is set to 0.1 μm to 0.5 μm.

As illustrated in FIG. 2, the outer peripheral portion of the stacked body of: the first electrode 12, the piezoelectric film 13, and the second electrode 14 of the sensor element 2 forms a tapered surface 2t such that the diameter gradually decreases from a lower side to an upper side. A tapered angle θ of the tapered surface 2t satisfies θ>90°. A size of a surface area is preferably set as the first electrode 12≥the piezoelectric film 13≥the second electrode 14 so that the tapered angle becomes greater. In this manner, the second electrode lead wiring portion 14b connected to the second electrode 14 is prevented from being bent at substantially a right angle. Accordingly, it is possible to prevent disconnection of the second electrode lead wiring portion 14b.

The protective layer 16 is formed on the first electrode lead wiring portion 12b and the second electrode lead wiring portion 14b. As an example, the protective layer 16 is formed by depositing a photosensitive polyimide material through a spin coating method. As an example, the thickness is set to 4 μm.

Next, an operation and an advantageous effect of the above-described configuration will be described. The piezoelectric tactile sensor 101 according to this embodiment has the piezoelectric film 13 located in a region smaller than the opening portion 3 of the substrate 1. In the piezoelectric tactile sensor 101, when the diaphragm 11 is deflected due to a minute force or vibration, the piezoelectric film 13 is deflected together with the diaphragm 11. In this manner, the piezoelectric tactile sensor 101 detects the applied force by using a voltage output from the two electrodes (the first electrode 12 and the second electrode 14). In this case, the piezoelectric film 13 is all located inside the opening portion 3 in the plane direction. Accordingly, there is no extension portion of the piezoelectric film 13 from the wall portion around the opening portion 3 to the frame portion 17. Therefore, the piezoelectric film 13 has a free end structure in all directions and has no support portion having a cantilever structure. Accordingly, the piezoelectric film 13 can expand and contract so that a bending moment does not act in all directions. Therefore, long-term reliability can be improved by suppressing variations in an output voltage.

In the above-described first embodiment, the insulating layer 15 is located in only a partial region of the outer peripheral portion of the sensor element 2. However, the insulating layer 15 may cover an entire surface of the sensor element 2. In this case, the insulating layer 15 may be configured to include a contact hole for drawing out the second electrode 14.

FIG. 4 is a plan view illustrating a configuration of a piezoelectric tactile sensor 201 according to the second embodiment. In FIG. 4, the same reference numerals will be given to elements the same as those in FIGS. 1 to 3, and description thereof will be omitted. The piezoelectric tactile sensor 201 according to this embodiment has a plurality of electrode terminal portions individually corresponding to each of nine sensor elements 2 arranged in the sensor element array 102. In this example, the piezoelectric tactile sensor 201 has nine first electrode terminal portions 12a1 to 12a9. The nine first electrode terminal portions 12a1 to 12a9 are individually connected to the first electrode 12 of each of the nine sensor elements 2 via individual first electrode lead wiring portions 12b1 to 12b9. The second electrode 14 of each of the nine sensor elements 2 is connected to one common second electrode terminal portion 14a via the shared second electrode lead wiring portion 14b.

According to this embodiment, a voltage output from each of the nine sensor elements 2 can be individually detected.

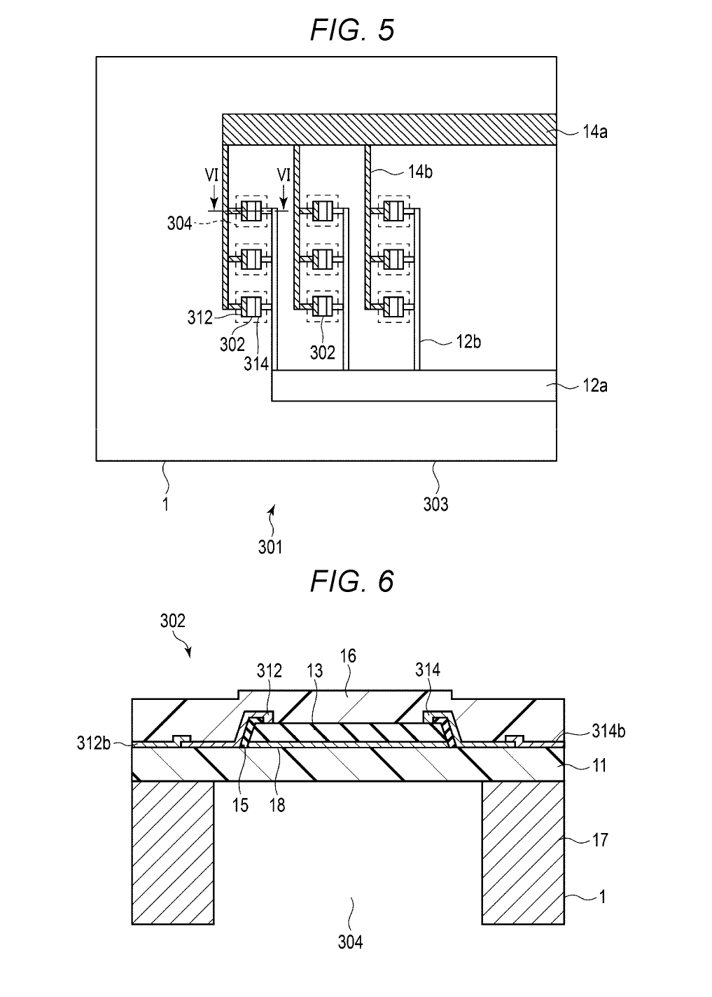

FIGS. 5 and 6 illustrate a third embodiment. FIG. 5 is a plan view illustrating a configuration of a piezoelectric tactile sensor 301 according to the third embodiment. FIG. 6 is a sectional view taken along line VI-VI in FIG. 5. In FIGS. 5 and 6, the same reference numerals will be given to elements the same as those in FIGS. 1 to 3, and description thereof will be omitted.

In the first embodiment, an example has been described in which the sensor element 2 is formed in a circular shape. However, the configuration is not limited thereto. The piezoelectric tactile sensor 301 according to this embodiment has a sensor element 302 having a rectangular shape as illustrated in FIG. 5.

A sensor element array 303 of the piezoelectric tactile sensor 301 according to this embodiment is configured so that a plurality of (for example, nine) sensor elements 302 having a square shape are arranged in a 3×3 matrix on the substrate 1 serving as the support body. The substrate 1 internally has nine square opening portions 304 for pressure detection.

FIG. 6 illustrates a sectional structure of one sensor element 302. The diaphragm 11 is integrally formed with the substrate 1 so as to cover an upper surface of the opening portion 304. An upper surface of the diaphragm 11 has the piezoelectric film 13. As an example, the diaphragm 11 and the piezoelectric film 13 are respectively formed of a silicon oxide film having a thickness of 4 μm and a lead zirconate titanate (PZT) having a thickness of 2 μm.

In order to form the piezoelectric film 13 having satisfactory crystallinity and orientation, a buffer layer 18 is stacked on the substrate 1 before the piezoelectric film 13 is formed. For example, the buffer layer 18 may be deposited using a single-layer material layer of platinum having the thickness of 0.1 to 0.2 μm or a multilayer material layer of SrTiO₃/MgO/TiN. As an example, one side of the opening portion 304 has a length of 200 μm, and an area thereof is 200×200 μm². As an example, one side of the piezoelectric film 13 has a length of 100 μm, and an area thereof is 100×100 μm².

In the first embodiment, the first electrode 12 and the second electrode 14 sandwich the piezoelectric film 13 and face each other in an upward-downward direction. In contrast, in this embodiment, the first electrode 312 and the second electrode 314 are formed on the upper surface of the piezoelectric film 13 in a laterally aligned state.

When the buffer layer 18 is formed of a conductive material, in order to electrically insulate the first electrode 312 and the second electrode 314 from the buffer layer 18, an insulating layer 15 is located in a portion of the outer peripheral portion of the sensor element 302. As an example, the thickness of the insulating layer 15 is set to 0.5 μm.

In order to draw out the first electrode 312 and the second electrode 314, a first electrode lead wiring portion 312b and a second electrode lead wiring portion 314b are respectively formed and connected to the first electrode 312 and the second electrode 314. As an example, the first electrode lead wiring portion 312b and the second electrode lead wiring portion 314b are formed by depositing gold through a sputtering method. As an example, the thickness is set to 0.1 μm to 0.5 μm.

The protective layer 16 is formed on the first electrode lead wiring portion 312b and the second electrode lead wiring portion 314b. As an example, the protective layer 16 is formed by depositing a photosensitive polyimide material through a spin coating method. As an example, the thickness is set to 4 μm.

In the first embodiment, a voltage (potential difference) is generated between the first electrode 12 and the second electrode 14 arranged in a direction orthogonal to the plane direction of the piezoelectric film 13. In this embodiment, the voltage (potential difference) is generated between the first electrode 312 and the second electrode 314 in the same direction as the plane direction of the piezoelectric film 13.

Therefore, according to the above-described respective embodiments, it is possible to provide the piezoelectric tactile sensor capable of suppressing variations in the output voltage so as to improve long-term reliability.

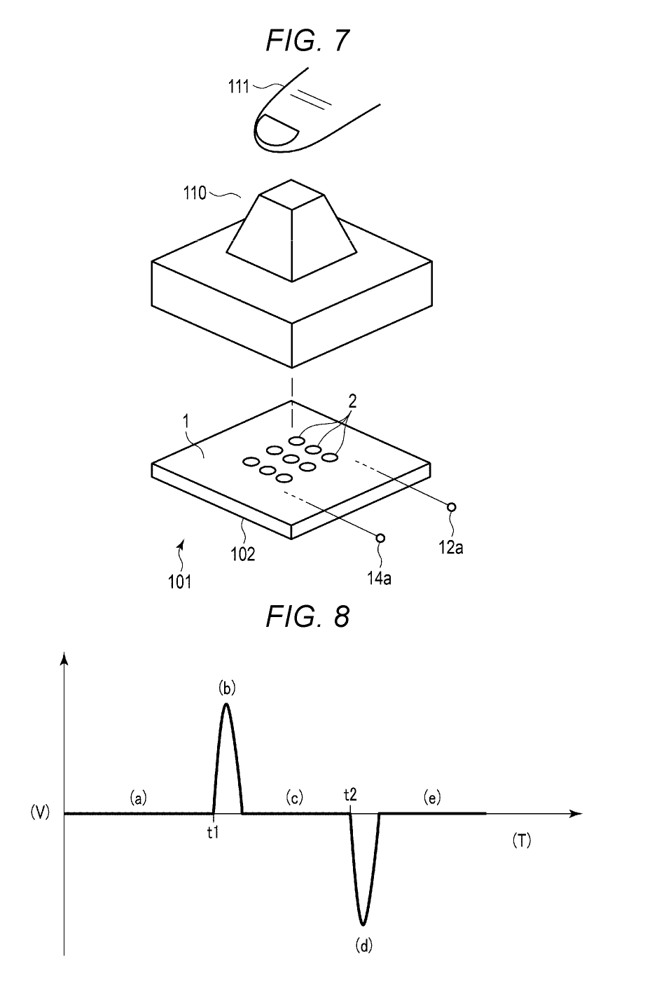

Next, an application example of the piezoelectric tactile sensor 101 according to the first embodiment will be described with reference to FIGS. 7 and 8. FIG. 7 is an exploded perspective view illustrating a configuration example of a keyboard device in an application example of the piezoelectric tactile sensor 101 according to the first embodiment. FIG. 8 is a characteristic diagram illustrating an example of a generated voltage according to the application example in FIG. 7. In FIG. 7, the same reference numerals will be given to elements the same as those in FIGS. 1 to 3, and description thereof will be omitted.

In a keyboard device according to this application example, a resin key 110 is located on the substrate 1 including the sensor element array 102. In this embodiment, if the resin key 110 is pressed at time t1, the sensor element array 102 is configured to be pressed.

In an initial state (i.e., a state where the resin key 110 is not pressed), the diaphragm 11 is not deflected. In this state, no voltage is generated by the piezoelectric film 13 (state of (a) in FIG. 8). Thereafter, if the key 110 is pressed at a time t1, the diaphragm 11 is deflected toward the opening portion 3 in a direction orthogonal to the plane direction of the substrate 1. As a result, the piezoelectric film 13 extends in the plane direction, thereby generating a positive voltage (state of (b) in FIG. 8).

If the key 110 is kept pressed, piezoelectric strain of the piezoelectric film 13 does not change. Accordingly, no voltage is generated by the piezoelectric film 13 (state of (c) in FIG. 8). Thereafter, if the key 110 is released at time t2, the diaphragm 11 is deflected in a direction opposite to that of (b) in FIG. 8, and the piezoelectric film 13 contracts in the plane direction so as to generate a negative voltage (state of (d) in FIG. 8). After the key 110 returns to the position in the initial state, the piezoelectric strain of the piezoelectric film 13 does not change. Therefore, the piezoelectric film 13 is in a state where no voltage is generated (state of (e) in FIG. 8).

As a usage scenario of the keyboard device according to this application example, precise and fine tracking is performed on the generated voltage. In this way, a difference in waveforms generated when each user types using the keyboard device is analyzed. This can be used as one of the biometric authentication methods based on the distinguishable features of a user's typing behavior on the keyboard.

For example, a waveform pattern (time required for pressing and releasing the key 110 or an interval required for typing one character and another character) of the user is pre-registered in a system. In this way, an original communication protocol for authentication is transmitted, thereby enabling the authentication. According to this typing authentication, it is possible to build a low-cost security system that does not require a special device such as a fingerprint reader and an IC card which detects a third party's attempt to perform an illegal operation.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A piezoelectric tactile sensor comprising:
a support body having one or more openings;
a diaphragm formed on a surface of the support body;
one or more piezoelectric films respectively formed above the openings and on a surface of the diaphragm; and
two electrodes for each of the piezoelectric films, the two electrodes sandwiching the corresponding piezoelectric film,
wherein each of the piezoelectric films has a diameter smaller than a diameter of a corresponding one of the openings and outputs a voltage to the two electrodes in response to a deflection of the diaphragm.

2. The piezoelectric tactile sensor according to claim 1, further comprising:
a first electrode terminal on the support body, connected to one of the two electrodes for each of the piezoelectric films; and
a second electrode terminal on the support body, connected to the other of the two electrodes for each of the piezoelectric films.

3. The piezoelectric tactile sensor according to claim 2, further comprising:
an insulating layer for each of the piezoelectric films that prevents one of the two electrodes from contacting at least one of the other of the two electrodes and the piezoelectric film.

4. The piezoelectric tactile sensor according to claim 2, further comprising:
an extension portion that connects one of the two electrodes for each of the piezoelectric films to the first electrode terminal.

5. The piezoelectric tactile sensor according to claim 1, further comprising:
one or more first electrode terminals on the support body, each connected to one of the two electrodes for the piezoelectric films; and
a second electrode terminal on the support body, connected to the other of the two electrodes for the piezoelectric films.

6. The piezoelectric tactile sensor according to claim 1,
wherein a stacked body formed by each of the piezoelectric films and the two electrodes forms a tapered surface in an outer peripheral portion of the stack body so as to prevent disconnection of a lead wire connected to one of the two electrodes.

7. The piezoelectric tactile sensor according to claim 6,
wherein the tapered surface is formed such that a surface area of one of the two electrodes on the diaphragm is greater than a surface area of each of the piezoelectric films, and the surface area of each of the piezoelectric films is greater than a surface area of the other of the two electrodes.

8. The piezoelectric tactile sensor according to claim 1,
wherein a thickness of the diaphragm is within a range of 1 to 50 μm.

9. The piezoelectric tactile sensor according to claim 1,
wherein a thickness of each of the two electrodes is within a range of 0.1 to 0.2 μm.

10. The piezoelectric tactile sensor according to claim 1,
the diameter of each of the piezoelectric films is smaller than 200 Jim.

11. A piezoelectric tactile sensor comprising:
a support body having one or more openings;
a diaphragm formed on a surface of the support body;
one or more piezoelectric films formed above the openings and on a surface of the diaphragm; and
two electrodes on an upper surface of each of the piezoelectric films and at opposite lateral sides of each of the piezoelectric films,
wherein each of the piezoelectric films has a width smaller than a width of each of the openings in a planar direction of the surface of the support body and outputs a voltage to the electrodes in response to a deflection of the diaphragm.

12. The piezoelectric tactile sensor according to claim 11, further comprising:
a first electrode terminal on the support body, connected to one of the two electrodes for each of the piezoelectric films; and
a second electrode terminal on the support body, connected to the other of the two electrodes for each of the piezoelectric films.

13. The piezoelectric tactile sensor according to claim 12, further comprising
two insulating layers for each of the piezoelectric films that prevents the two electrodes from contacting the piezoelectric film.

14. The piezoelectric tactile sensor according to claim 11, further comprising
a buffer layer between each of the piezoelectric films and the diaphragm.

15. The piezoelectric tactile sensor according to claim 14,
wherein a stacked body formed by each of the piezoelectric films and the buffer layer forms a tapered surface in an outer peripheral portion of the stacked body so as to prevent disconnection of a lead wire connected to one of the two electrodes.

16. The piezoelectric tactile sensor according to claim 11,
wherein a thickness of the diaphragm is within a range of 1 to 50 μm.

17. The piezoelectric tactile sensor according to claim 11,
wherein a thickness of each of the two electrodes is within a range of 0.1 to 0.2 μm.

18. The piezoelectric tactile sensor according to claim 11,
the width of each of the piezoelectric films is smaller than 200 μm.

19. A keyboard device comprising:
a support body;
a plurality of piezoelectric tactile sensors; and
a plurality of keys arranged on the piezoelectric tactile sensors, respectively,
wherein each of the piezoelectric tactile sensors comprises an opening in the support body, a diaphragm that covers the opening, a piezoelectric film formed above the openings and on a surface of the diaphragm, and two electrodes that sandwich the piezoelectric film, the piezoelectric film having a width smaller than a width of the opening and outputting a voltage to the two electrodes in response to a deflection of the diaphragm.

20. The keyboard device according to claim 19, wherein the two electrodes are located at respective opposing surfaces of the piezoelectric film or at respective opposing lateral sides of the piezoelectric film.
